(19) United States
(12) Patent Application Publication
(10) Pub. No.: US 2025/0380515 A1
(43) Pub. Date: Dec. 11, 2025

(54) PHOTO DETECTOR

(71) Applicant: NTT, Inc., Tokyo (JP)

(72) Inventors: Yosuke Hinakura, Tokyo (JP); Shin Kamei, Tokyo (JP); Yusuke Nasu, Tokyo (JP); Yuichiro Ikuma, Tokyo (JP)

(21) Appl. No.: 18/876,917

(22) PCT Filed: Jun. 22, 2022
(86) PCT No.: PCT/JP2022/024807

§ 371 Date: Dec. 19, 2024

(51) Int. Cl. H10F 30/223; H10F 77/40

(52) U.S. Cl. CPC H10F 30/223; H10F 77/413

(57) ABSTRACT

A photo detector includes a first cladding layer, a first semiconductor layer of a first conductivity type on the first cladding layer, a light absorption layer on the first semiconductor layer, a second semiconductor layer of a second conductivity type on the light absorption layer, a second cladding layer on the first semiconductor layer, the second cladding layer covering the light absorption layer and the second semiconductor layer, and a plurality of columnar vias penetrating the second cladding layer and connected with the second semiconductor layer, where the plurality of columnar vias are arranged in an arrangement direction parallel to a surface of the first semiconductor layer on which the light absorption layer is disposed, and a coverage factor in plan view of each of the plurality of columnar vias decreases from a first end side to a second end side in the arrangement direction of the light absorption layer.

### CROSS-REFERENCE TO RELATED APPLICATIONS

This application is a national phase entry of PCT Application No.

PCT/JP2022/024807, filed on Jun. 22, 2022, which application is hereby incorporated herein by reference.

### TECHNICAL FIELD

The present invention relates to a photo detector.

### BACKGROUND

With the recent spread of optical communication, cost reduction of an optical communication device is required. In response to such a request, for example, there is a technology of forming an optical circuit constituting an optical communication device on a large-diameter wafer such as a silicon wafer using a minute optical circuit technology such as silicon photonics. According to this technology, it is possible to collectively form chips of a large number of optical circuits, dramatically reduce the material cost per chip, and reduce the cost of the optical communication device. As a representative device using such a technology, there is a photo detector in which a vertical photodiode having layers stacked therein and a waveguide are coupled (see Patent Literature 1). There is also a technology in which an electrode disposed on a light absorption layer in the above type of photo detector is divided into a plurality of columnar vias and disposed while avoiding an optical mode distribution (see Patent Literature 1 and Non Patent Literature 1).

Hereinafter, a configuration in which a photocurrent detection electrode disposed on a light absorption layer is divided into a plurality of columnar vias in a photo detector in which a vertical photodiode and a waveguide are coupled will be described with reference to FIGS. 6A and 6B. Note that the drawings are schematic.

First, the photo detector includes a lower cladding layer 301 formed on a substrate 321, and a p-type layer 302 formed on the lower cladding layer 301. The p-type layer 302 is formed by introducing impurities into a predetermined region of a semiconductor layer 311 formed on and in contact with the lower cladding layer 301. The semiconductor layer 311 is made of silicon, for example.

The photo detector also includes a light absorption layer 303 extending in a waveguide direction and formed on the p-type layer 302, and an n-type layer 304 formed on the light absorption layer 303. The light absorption layer 303 is formed in a so-called core shape, and in this example, the shape of the cross section perpendicular to the waveguide direction is a trapezoid. Moreover, the light absorption layer 303 is made of germanium, for example, and is of an i-type or an n-type. Moreover, the n-type layer 304 is formed by introducing impurities, at a high concentration, into a predetermined region in the upper surface of the light absorption layer 303.

The photo detector also includes an upper cladding layer 305 formed on the p-type layer 302 so as to cover the light absorption layer 303 and the n-type layer 304, and a plurality of columnar vias 306 penetrating the upper cladding layer 305 and connected (ohmic contact) with the n-type layer 304. The plurality of columnar vias 306 is connected with a first electrode 307 formed on the upper cladding layer 305. Moreover, second electrodes 314 and 315 penetrating the upper cladding layer 305 and connected with the p-type layer 302 are provided on the upper cladding layer 305 on sides of the light absorption layer 303 in a direction intersecting the waveguide direction. Contact layers 312 and 313 including impurities introduced therein at a high concentration are formed in regions where the second electrodes 314 and 315 are in contact with the p-type layer 302.

Moreover, in the photo detector, an optical waveguide 331 is optically connected with one end side in the waveguide direction of the light absorption layer 303. Signal light guided through the optical waveguide 331 enters the light absorption layer 303 of the photo detector. A stacked structure of the p-type layer 302, the light absorption layer 303, and the n-type layer 304 constitutes a photodiode. In a case where the light absorption layer 303 is of an i-type, a p-i-n photodiode is formed. Moreover, in a case where the light absorption layer 303 is of an n-type, a pn photodiode is formed. Note that, in the plan view of FIG. 6A, depiction of the substrate 321 and the lower cladding layer 301 illustrated in the cross-sectional view of FIG. 6B is omitted.

Signal light that entering from the optical waveguide 331 is mainly absorbed by the light absorption layer 303, and carriers are generated. The generated carriers cause a photocurrent to flow across the first electrode 307 and the second electrodes 314 and 315 for photocurrent detection, and light is detected by detecting the photocurrent.

### CITATION LIST

### Patent Literature

Patent Literature 1: JP 6836547 B2

Patent Literature 2: U.S. Pat. No. 7,613,369

### Non Patent Literature

Non Patent Literature 1: G. Li et al., “Improving CMOS-compatible Germanium photo detectors”, Optics Express, vol. 20, no. 24, pp. 26345-26350, 2012.

### SUMMARY

### Technical Problem

By the way, although the technology described above avoids an optical mode distribution by dividing an electrode disposed on the light absorption layer into a plurality of columnar vias, the high-speed responsiveness lowers with the increase in electric resistance, though the light receiving sensitivity is improved, when the area of the via electrode in the vicinity of the optical mode in plan view is decreased (the coverage factor of the via electrodes is decreased). Moreover, the volume ratio of a region where the electric field is generated in the light absorption region is reduced, and the space charge effect (the effect that the electric charge generated by the light absorption weakens the electric field in the light absorption region) is likely to occur. As a result, the output photocurrent is saturated with respect to the high-power optical input, and the high-speed responsiveness lowers.

On the other hand, when the area of the via electrode in plan view is increased (the coverage factor of the via electrodes is increased), the light receiving sensitivity lowers, though the high-speed responsiveness is improved. As described above, in this type of photo detector, the high-speed responsiveness and the light receiving sensitivity are in a trade-off relationship.

Embodiments of the present invention has been made to solve the above problems, and it is an object thereof to improve one characteristic of high-speed responsiveness and light receiving sensitivity while suppressing deterioration of the other characteristic in a photo detector in which a vertical photodiode and a waveguide are coupled.

Solution to Problem

A photo detector according to embodiments of the present invention includes: a first conductivity type layer of a first conductivity type formed on a lower cladding layer; a light absorption layer extending in a waveguide direction and formed on the first conductivity type layer; a second conductivity type layer of a second conductivity type formed on the light absorption layer; an upper cladding layer formed on the first conductivity type layer so as to cover the light absorption layer and the second conductivity type layer; and a plurality of columnar vias penetrating the upper cladding layer and connected with the second conductivity type layer, the plurality of columnar vias are formed to be arranged in the waveguide direction, and a coverage factor in plan view decreases from one end side to the other end side in the waveguide direction of the light absorption layer.

### Advantageous Effects

As described above, according to embodiments of the present invention, the plurality of columnar vias are formed to be arranged in the waveguide direction, and the coverage factor in plan view decreases from one end side to the other end side in the waveguide direction of the light absorption layer, so that it is possible to improve one characteristic of high-speed responsiveness and light receiving sensitivity while suppressing deterioration of the other characteristic.

### BRIEF DESCRIPTION OF THE DRAWINGS

FIG. 1A is a plan view illustrating a configuration of a photo detector according to a first embodiment of the present invention.

FIG. 1B is a cross-sectional view illustrating a configuration of the photo detector according to the first embodiment of the present invention.

FIG. 2 is a characteristic diagram illustrating a simulation result regarding electric resistance in a case where a plurality of columnar vias has the same cross-sectional area, a case of the first embodiment, and a case where the columnar vias are integrally formed.

FIG. 3 is a characteristic diagram illustrating a simulation result regarding sensitivity in a case where a plurality of columnar vias has the same cross-sectional area (dot and dash line), a case of the first embodiment (solid line), and a case where the columnar vias are integrally formed (broken line).

FIG. 4 is a plan view illustrating a configuration of a photo detector according to a second embodiment of the present invention.

FIG. 5 is a plan view illustrating a configuration of a photo detector according to a third embodiment of the present invention.

FIG. 6A is a plan view illustrating a configuration of a conventional photo detector.

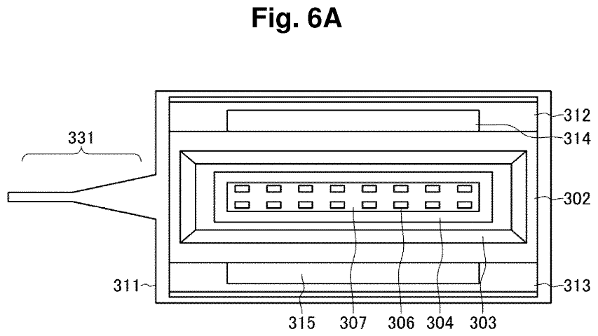

FIG. 6B is a cross-sectional view illustrating a configuration of the conventional photo detector.

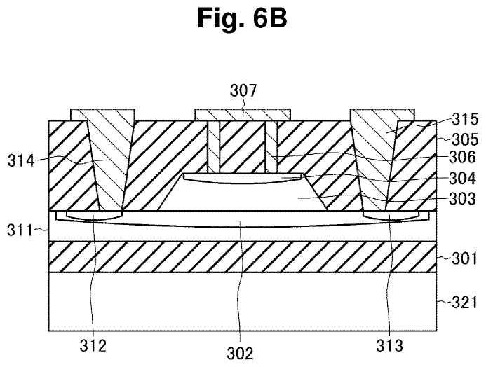

### DETAILED DESCRIPTION OF ILLUSTRATIVE EMBODIMENTS

Hereinafter, photo detectors according to embodiments of the present invention will be described.

### First Embodiment

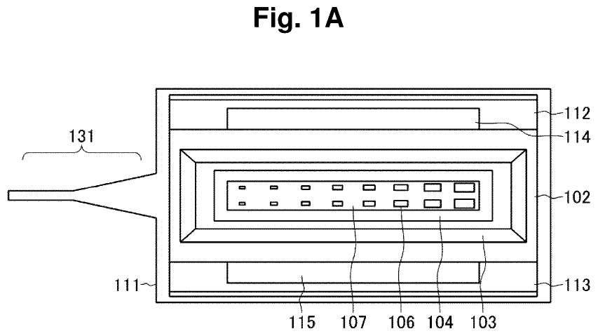

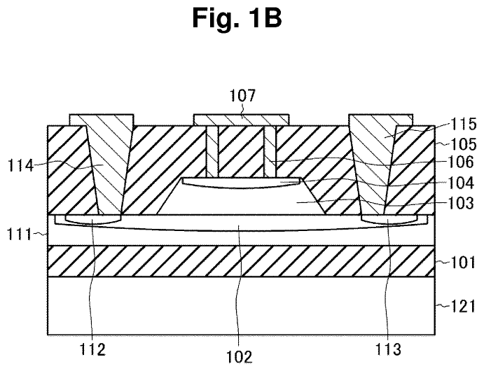

First, a photo detector according to a first embodiment of the present invention will be described with reference to FIGS. 1A and 1B. Note that the drawings are schematic.

First, the photo detector includes a lower cladding layer 101 formed on a substrate 121, and a first conductivity type layer 102 of a first conductivity type formed on the lower cladding layer 101. The first conductivity type layer 102 is formed by introducing impurities of the first conductivity type into a predetermined region of a semiconductor layer 111 formed on and in contact with the lower cladding layer 101. The first conductivity type can be a p-type, for example. In this case, the second conductivity type described later is an n-type. Moreover, the first conductivity type can be an n-type. In this case, the second conductivity type described later is a p-type. The semiconductor layer 111 can be made of silicon, for example. The lower cladding layer 101 can be made of silicon oxide, for example.

The photo detector also includes a light absorption layer 103 extending in the waveguide direction and formed on the first conductivity type layer 102, and a second conductivity type layer 104 of the second conductivity type formed on the light absorption layer 103. The light absorption layer 103 is formed in a so-called core shape, and in this example, the shape of the cross section perpendicular to the waveguide direction is a trapezoid. Moreover, the light absorption layer 103 is made of germanium, for example, and is of an i-type or the second conductivity type. Moreover, the second conductivity type layer 104 is formed by introducing impurities, at a high concentration, into a predetermined region in the upper surface of the light absorption layer 103.

The photo detector also includes an upper cladding layer 105 formed on the first conductivity type layer 102 so as to cover the light absorption layer 103 and the second conductivity type layer 104, and a plurality of columnar vias 106 penetrating the upper cladding layer 105 and connected (ohmic contact) with the second conductivity type layer 104. The upper cladding layer 105 can be made of silicon oxide, for example. The columnar vias 106 can be made of predetermined metal. Moreover, the plurality of columnar vias 106 are provided at positions where light absorption or light scattering does not occur in the vicinity of the plurality of columnar vias 106 when light entering the light absorption layer 103 propagates through the light absorption layer 103.

Here, the plurality of columnar vias 106 is formed to be arranged in the waveguide direction, and the coverage factor in plan view gradually decreases from one end side to the other end side in the waveguide direction of the light absorption layer 103. In other words, the ratio of the exclusive area of the plurality of columnar vias 106 changes from one end side to the other end side in the waveguide direction of the light absorption layer 103.

In the first embodiment, the cross-sectional area of the plurality of columnar vias 106 in a plane parallel to the surface of the lower cladding layer 101 gradually decreases from one end side to the other end side in the waveguide direction. Moreover, in this example, the plurality of columnar vias 106 is formed to be arranged in two rows in the waveguide direction. Moreover, although each of the plurality of columnar vias 106 has a rectangular cross-sectional shape in a plane (a plane parallel to the surface of the lower cladding layer 101) perpendicular to the direction in which the columnar via 106 extends in this example, the present invention is not limited thereto, and the cross-sectional shape may be a circle, an ellipse, or a polygon such as a pentagon or a hexagon. Moreover, although the cross-sectional area can be changed linearly, the present invention is not limited thereto, and the cross-sectional area can also be changed nonlinearly.

Note that the plurality of columnar vias 106 is connected with a first electrode 107 formed on the upper cladding layer 105. Moreover, second electrodes 114 and 115 penetrating the upper cladding layer 105 and connected with the first conductivity type layer 102 are provided on the upper cladding layer 105 on sides of the light absorption layer 103 in a direction intersecting the waveguide direction. Contact layers 112 and 113 including impurities of the first conductivity type introduced therein at a high concentration are formed in a region where the second electrodes 114 and 115 are in contact with the first conductivity type layer 102. The second electrodes 114 and 115 can be made of predetermined metal.

Moreover, in this example, an optical waveguide 131 is optically connected with one end side in the waveguide direction of the light absorption layer 103. Signal light guided through the optical waveguide 131 enters the light absorption layer 103 of the photo detector. A stacked structure of the first conductivity type layer 102, the light absorption layer 103, and the second conductivity type layer 104 constitutes a photodiode. In a case where the light absorption layer 103 is of an i-type, a p-i-n photodiode is formed. Moreover, in a case where the light absorption layer 103 is of the second conductivity type, a pn photodiode is formed. Note that, in the plan view of FIG. 1A, depiction of the substrate 121 and the lower cladding layer 101 illustrated in the cross-sectional view of FIG. 1B is omitted.

Signal light entering from the optical waveguide 131 is mainly absorbed by the light absorption layer 103, and carriers are generated. The generated carriers cause a photocurrent to flow across the first electrode 107 and the second electrodes 114 and 115 for photocurrent detection, and light is detected by detecting the photocurrent. The first embodiment is constructed such that signal light enters from one end side in the waveguide direction of the light absorption layer 103.

Here, although the highest optical power exists on one end side in the waveguide direction of the light absorption layer 103 serving as a light input potion to which signal light from the optical waveguide 131 enters, the optical power remaining in the photodiode including the light absorption layer 103 decreases exponentially as the light is guided (propagated) in the waveguide direction.

In the first embodiment, since the cross-sectional area of a columnar via 106 in the vicinity of the light input potion in a plane parallel to the surface of the lower cladding layer 101 is smaller than that of a columnar via 106 at a position away from the light input potion, the optical loss in a state where the remaining optical power is large can be suppressed to be small. Moreover, since the cross-sectional area of a columnar via 106 at a position away from the light input potion is larger than that of a columnar via 106 in the vicinity of the light input potion, an increase in the electric resistance value due to the division can be suppressed to be small. On the other hand, although the optical loss is large at a position away from the light input potion, the remaining optical power is already small, and thus the ratio of the power lost in this part is small with respect to the entire input optical power.

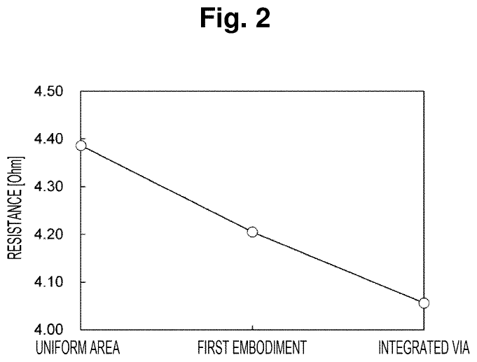

As a result, according to the first embodiment, an increase in electric resistance is minimized while an effect of improving photodetection sensitivity equivalent to that of the conventional technique is obtained. FIG. 2 illustrates a simulation result regarding electric resistance. A case where the plurality of columnar vias has the same cross-sectional area, a case of the first embodiment, and a case where the columnar vias are integrally formed are compared. As illustrated in FIG. 2, the electric resistance can be reduced according to the first embodiment as compared with a case where the plurality of columnar vias has the same cross-sectional area.

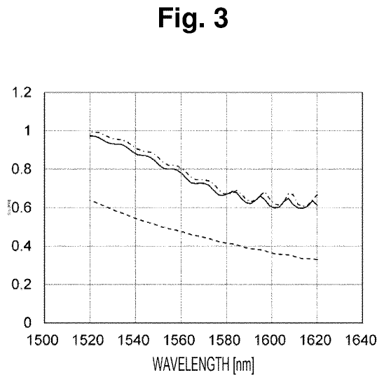

Moreover, FIG. 3 illustrates a simulation result regarding sensitivity. A case where the plurality of columnar vias has the same cross-sectional area (dot and dash line), a case of the first embodiment (solid line), and a case where the columnar vias are integrally formed (broken line) are compared. As illustrated in FIG. 3, the sensitivity can be improved according to the first embodiment as compared with a case where the columnar vias are integrally formed.

By the way, although the coverage factor of the columnar vias 106 is decreased in the vicinity of the light input potion where the remaining optical power is high and the coverage factor is increased in the rear where the remaining optical power is low in the example described above so that the deterioration of the high-speed responsiveness is minimized while the light receiving sensitivity is improved, the present invention is not limited thereto.

For example, by adopting a configuration in which signal light enters from the other end side in the waveguide direction of the light absorption layer 103, the coverage factor of the columnar vias 106 is increased in the vicinity of the light input potion where the remaining optical power is high and a large amount of electric charge is likely to be generated while the coverage factor of the columnar vias 106 is decreased in the rear where only a small amount of electric charge is generated, so that it is possible to minimize the lowering of the light receiving sensitivity while improving the linearity and the high-speed responsiveness of the output photocurrent with respect to the high-power optical input.

As described above, according to the first embodiment, it is possible to improve one characteristic of high-speed responsiveness and light receiving sensitivity while suppressing deterioration of the other characteristic in the photo detector in which the vertical photodiode and the waveguide are coupled.

### Second Embodiment

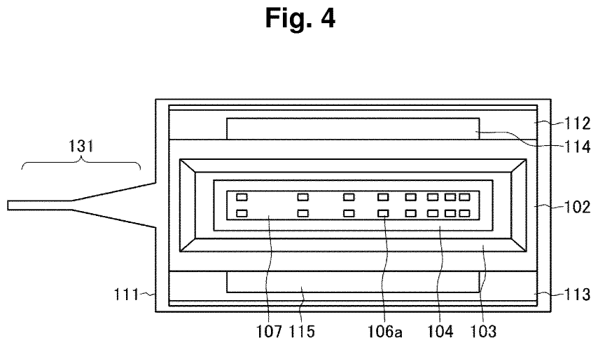

Next, a photo detector according to a second embodiment of the present invention will be described with reference to FIG. 4. Note that the drawings are schematic.

This photo detector has a configuration similar to that of the first embodiment described above, and includes a plurality of columnar vias 106a penetrating the upper cladding layer 105 and connected with the second conductivity type layer 104 in the second embodiment. Also in the second embodiment, the plurality of columnar vias 106a is formed to be arranged in the waveguide direction, and the coverage factor in plan view gradually decreases from one end side to the other end side in the waveguide direction of the light absorption layer 103.

In the second embodiment, regarding the plurality of columnar vias 106a, an interval between columnar vias 106a adjacent in the waveguide direction gradually increases from one end side to the other end side in the waveguide direction. Note that, also in this example, the plurality of columnar vias 106a is formed to be arranged in two rows in the waveguide direction. Moreover, although each of the plurality of columnar vias 106a has a rectangular cross-sectional shape in a plane (a plane parallel to the surface of the lower cladding layer 101) perpendicular to the direction in which the columnar via 106a extends in this example, the present invention is not limited thereto, and the cross-sectional shape may be a circle, an ellipse, or a polygon such as a pentagon or a hexagon. Moreover, although the interval between columnar vias 106a adjacent in the waveguide direction can be changed linearly, the present invention is not limited thereto, and the interval can be changed nonlinearly.

In the second embodiment, since the number of the columnar vias 106a in the vicinity of the light input potion per unit area is smaller than that of the columnar vias 106a at positions away from the light input potion, the optical loss in a state where the remaining optical power is large can be suppressed to be small. Moreover, since the number of the columnar vias 106a at positions away from the light input potion per unit area is larger than that of the columnar vias 106a in the vicinity of the light input potion, an increase in the electric resistance value due to the division can be suppressed to be small. On the other hand, although the optical loss is large at a position away from the light input potion, the remaining optical power is already small, and thus the ratio of the power lost in this part is small with respect to the entire input optical power. As a result, also in the second embodiment, an increase in electric resistance is minimized while an effect of improving photodetection sensitivity equivalent to that of the conventional technique is obtained.

By the way, although the coverage factor is decreased by reducing the number of the columnar vias 106a per unit area in the vicinity of the light input potion having high remaining optical power and the coverage factor is increased by increasing the number of the columnar vias per unit area in the rear where the remaining optical power is low in the example described above so that deterioration of the high-speed responsiveness is minimized while the light receiving sensitivity is improved, the present invention is not limited thereto.

For example, by adopting a configuration in which signal light enters from the other end side in the waveguide direction of the light absorption layer 103, the coverage factor of the columnar vias 106a is increased in the vicinity of the light input potion where the remaining optical power is high and a large amount of electric charge is likely to be generated while the coverage factor of the columnar vias 106a is decreased in the rear where only a small amount of electric charge is generated, so that it is possible to minimize the lowering of the light receiving sensitivity while improving the linearity and the high-speed responsiveness of the output photocurrent with respect to the high-power optical input.

As described above, also in the second embodiment, it is possible to improve one characteristic of high-speed responsiveness and light receiving sensitivity while suppressing deterioration of the other characteristic in the photo detector in which the vertical photodiode and the waveguide are coupled.

### Third Embodiment

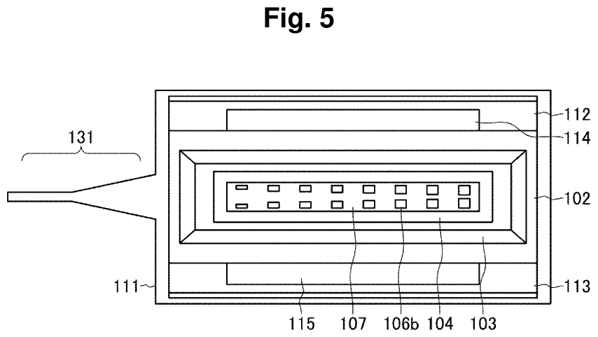

Next, a photo detector according to a third embodiment of the present invention will be described with reference to FIG. 5. Note that the drawings are schematic.

This photo detector has a configuration similar to that of the first embodiment described above, and includes a plurality of columnar vias 106b penetrating the upper cladding layer 105 and connected with the second conductivity type layer 104 in the third embodiment. Also in the third embodiment, the plurality of columnar vias 106b is formed to be arranged in the waveguide direction, and the coverage factor in plan view gradually decreases from one end side to the other end side in the waveguide direction of the light absorption layer 103.

In the third embodiment, the plurality of columnar vias 106b is formed to be arranged in two rows in the waveguide direction, and the position of the center of gravity in plan view changes so as to be shifted more greatly toward the center side of the two rows from one end side to the other end side in the waveguide direction. In this example, the positions of the outer side surfaces of the two rows of the plurality of columnar vias 106b arranged in two rows are common, and the position of the center of gravity is shifted by gradually increasing the length in a direction perpendicular to the waveguide direction in a plane parallel to the surface of the lower cladding layer 101 from one end side to the other end side in the waveguide direction. The cross-sectional area of the plurality of columnar vias 106b in a plane parallel to the surface of the lower cladding layer 101 gradually increases from one end side to the other end side in the waveguide direction.

Note that, also in this example, the plurality of columnar vias 106b is formed to be arranged in two rows in the waveguide direction. Moreover, although each of the plurality of columnar vias 106b has a rectangular cross-sectional shape in a plane (a plane parallel to the surface of the lower cladding layer 101) perpendicular to the direction in which the columnar via 106b extends in this example, the present invention is not limited thereto, and the cross-sectional shape may be a circle, an ellipse, or a polygon such as a pentagon or a hexagon. Moreover, the position of the center of gravity in plan view can be changed so as to be shifted more greatly toward the center side of the two rows from the other end side to the one end side in the waveguide direction.

In the third embodiment, since each columnar via 106b in the vicinity of the light input potion has a small cross-sectional area, and the distance between the optical mode and the center of gravity of the cross section is long, the optical loss in a state where the optical power is large can be suppressed to be small. Since each columnar via 106b located away from the light input potion has a large cross-sectional area, and the distance between the optical mode and the center of gravity of the via cross section is short, the increase in the electric resistance value due to the division can be suppressed to be small. On the other hand, although the optical loss is large, since the remaining optical power is already small, the ratio of the power lost in this part is small with respect to the entire input optical power. As a result, also in the third embodiment, an increase in electric resistance is minimized while an effect of improving photodetection sensitivity equivalent to that of the conventional technique is obtained.

By the way, although the coverage factor is decreased by reducing the number of the columnar vias 106b per unit area in the vicinity of the light input potion having high remaining optical power and the coverage factor is increased by increasing the number of the columnar vias per unit area in the rear where the remaining optical power is low in the example described above so that deterioration of the high-speed responsiveness is minimized while the light receiving sensitivity is improved, the present invention is not limited thereto.

For example, by adopting a configuration in which signal light enters from the other end side in the waveguide direction of the light absorption layer 103, the coverage factor of the columnar vias 106b is increased in the vicinity of the light input potion where the remaining optical power is high and a large amount of electric charge is likely to be generated while the coverage factor of the columnar vias 106b is decreased in the rear where only a small amount of electric charge is generated, so that it is possible to minimize the lowering of the light receiving sensitivity while improving the linearity and the high-speed responsiveness of the output photocurrent with respect to the high-power optical input.

As described above, also in the third embodiment, it is possible to improve one characteristic of high-speed responsiveness and light receiving sensitivity while suppressing deterioration of the other characteristic in the photo detector in which the vertical photodiode and the waveguide are coupled.

As described above, according to embodiments of the present invention, the plurality of columnar vias connected with the second semiconductor layer formed on the light absorption layer is formed to be arranged in the waveguide direction, and the coverage factor in plan view is decreased from one end side to the other end side in the waveguide direction of the light absorption layer, so that it is possible to improve one characteristic of high-speed responsiveness and light receiving sensitivity while suppressing deterioration of the other characteristic.

Some or all of the embodiments described above are also described as the following supplementary notes, but are not limited thereto.

### Supplementary Note 1

A photo detector including:
a first semiconductor layer of a first conductivity type formed on a lower cladding layer;
a light absorption layer extending in a waveguide direction and formed on the first semiconductor layer;
a second semiconductor layer of a second conductivity type formed on the light absorption layer;
an upper cladding layer formed on the first semiconductor layer so as to cover the light absorption layer and the second semiconductor layer; and
a plurality of columnar vias penetrating the upper cladding layer and connected with the second semiconductor layer,
in which the plurality of columnar vias are formed to be arranged in the waveguide direction, and a coverage factor in plan view decreases from one end side to the other end side in the waveguide direction of the light absorption layer.

### Supplementary Note 2

The photo detector according to supplementary note 1, in which a cross-sectional area of the plurality of columnar vias in a plane parallel to a surface of the lower cladding layer decreases from one end side to the other end side in the waveguide direction.

### Supplementary Note 3

The photo detector according to supplementary note 1 or 2, in which an interval between columnar vias of the plurality of columnar vias that are adjacent to each other in the waveguide direction increases from one end side to the other end side in the waveguide direction.

### Supplementary Note 4

The photo detector according to any one of supplementary notes 1 to 3, in which the plurality of columnar vias is formed to be arranged in two rows in the waveguide direction, and a position of a center of gravity in plan view changes so as to be shifted more greatly toward a center side of the two rows from one end side to the other end side in the waveguide direction.

### Supplementary Note 5

The photo detector according to any one of supplementary notes 1 to 4, in which the plurality of columnar vias is provided at positions where light absorption or light scattering does not occur in the vicinity of the plurality of columnar vias when light entering the light absorption layer propagates through the light absorption layer.

### Supplementary Note 6

The photo detector according to any one of supplementary notes 1 to 5, in which signal light enters from one end side or the other end side in the waveguide direction of the light absorption layer.

Note that the present invention is not limited to the embodiments described above, and it is apparent that various modifications and combinations can be implemented by those skilled in the art without departing from the technical spirit of the present invention.

### Reference Signs List

101 Lower cladding layer
102 First conductivity type layer
103 Light absorption layer
104 Second conductivity type layer
105 Upper cladding layer
106 Columnar via
107 First electrode
111 Semiconductor layer
112 Contact layer
113 Contact layer
114 Second electrode
115 Second electrode
131 Optical waveguide

1-6. (canceled)

7. A photo detector comprising:
a first cladding layer;
a first semiconductor layer of a first conductivity type on the first cladding layer;
a light absorption layer on the first semiconductor layer;
a second semiconductor layer of a second conductivity type on the light absorption layer;
a second cladding layer on the first semiconductor layer, the second cladding layer covering the light absorption layer and the second semiconductor layer; and
a plurality of columnar vias penetrating the second cladding layer and connected with the second semiconductor layer,
wherein the plurality of columnar vias are arranged in an arrangement direction parallel to a surface of the first semiconductor layer on which the light absorption layer is disposed, and a coverage factor in plan view of each of the plurality of columnar vias decreases from a first end side to a second end side in the arrangement direction of the light absorption layer.

8. The photo detector according to claim 7, wherein a cross-sectional area of the plurality of columnar vias in a plane parallel to the surface of the first semiconductor layer decreases along the arrangement direction.

9. The photo detector according to claim 7, wherein an interval between the plurality of columnar vias that are adjacent to each other in the arrangement direction increases from the first side to the second end side in the arrangement direction.

10. The photo detector according to claim 7, wherein the plurality of columnar vias are arranged in two rows in the arrangement direction, and center of gravity positions of the plurality of columnar vias in plan view changes so as to be shifted more greatly toward a center between the two rows from the first side to the second end side in the arrangement direction.

11. The photo detector according to claim 7, wherein the plurality of columnar vias are configured where light absorption or light scattering does not occur in a vicinity of the plurality of columnar vias when light entering the light absorption layer propagates through the light absorption layer.

12. The photo detector according to claim 7, wherein the light absorption layer allows signal light to enter the light absorption layer from the first side of the light absorption layer in the arrangement direction.

13. The photo detector according to claim 12, further comprising an optical waveguide optically coupled to the first end side of the light absorption layer and configured to transmit the signal light into the light absorption layer.

14. A photo detector comprising:
a lower cladding layer;
a first semiconductor layer of a first conductivity type over the lower cladding layer;
a light absorption layer extending in a waveguide direction and over the first semiconductor layer;
a second semiconductor layer of a second conductivity type over the light absorption layer;
an upper cladding layer over the first semiconductor layer, the upper cladding layer covering the light absorption layer and the second semiconductor layer; and
a plurality of columnar vias penetrating the upper cladding layer and connected with the second semiconductor layer,
wherein the plurality of columnar vias are arranged in the waveguide direction, and
wherein a coverage factor in plan view of the plurality of columnar vias decreases from a first end side to a second end side in the waveguide direction of the light absorption layer.

15. The photo detector according to claim 14, wherein a cross-sectional area of the plurality of columnar vias in a plane parallel to a surface of the lower cladding layer decreases from the first end side to the second end side in the waveguide direction.

16. The photo detector according to claim 14, wherein an interval between columnar vias of the plurality of columnar vias that are adjacent to each other in the waveguide direction increases from the first end side to the second end side in the waveguide direction.

17. The photo detector according to claim 14, wherein the plurality of columnar vias are arranged in two rows in the waveguide direction, and a position of a center of gravity in plan view of the plurality of columnar vias changes so as to be shifted more greatly toward a center side of the two rows from the first end side to the second end side in the waveguide direction.

18. The photo detector according to claim 14, wherein the plurality of columnar vias are provided at positions where light absorption or light scattering may not occur in a vicinity of the plurality of columnar vias when light entering the light absorption layer propagates through the light absorption layer.

19. The photo detector according to claim 14, wherein signal light may enter the light absorption layer from the first end side or the second end side in the waveguide direction.

20. The photo detector according to claim 14, further comprising an optical waveguide optically connected with the first end side in the waveguide direction of the light absorption layer.
